(19) United States
(12) Patent Application Publication
(10) Pub. No.: US 2013/0113640 A1
(43) Pub. Date: May 9, 2013

(54) DIGITAL-TO-ANALOG CONVERTING DEVICE

(71) Applicants: Chen-Jung CHUANG, New Taipei City (TW); Tai-Shin Tang, Taichung City (TW)

(72) Inventors: Chen-Jung CHUANG, New Taipei City (TW); Tai-Shin Tang, Taichung City (TW)

(21) Appl. No.: 13/358,870

(22) Filed: Jan. 26, 2012

(30) Foreign Application Priority Data
Nov. 9, 2011 (TW) 100140912

(51) Int. Cl. H03M 1/66

(52) U.S. Cl. 341/136; 341/144

(57) ABSTRACT

A digital-to-analog converting device converts an N-bit digital input signal into an analog signal using M reference voltages, where N>3 and M=2^{(N-2)}+1, and includes: a decoding unit operable based on third to N^{th} bits of the digital input signal and reference voltages to output first and second decoding voltages; and an output unit operable based on the first and second decoding voltages and first and second bits of the digital input signal to generate the analog signal. The decoding unit includes K first selectors and a second selector consisting of first and second decoding circuits, where K=2^{(N-3)}+1.

### CROSS-REFERENCE TO RELATED APPLICATION

This application claims priority to Taiwanese Application No. 100140912, filed on Nov. 9, 2011.

### BACKGROUND OF THE INVENTION

1. Field of the Invention

The invention relates to a signal converting device, and more particularly to a digital-to-analog converting device.

2. Description of the Related Art

Referring to FIG. 1, a conventional 8-bit digital-to-analog converting device 900 is shown to convert a digital input signal with eight bits indicated by B(7:0) into an analog signal (V_{analog}) using 65 reference voltages (V₁˜V₆₅) forming an arithmetic progression, wherein V₁=1V, V₂=5V, V₃=9V, . . . , V₆₄=253V, and V₆₅=257V. The conventional digital-to-analog converting device 900 includes a first decoding unit 7, a second decoding unit 8, and an output unit 9.

The first decoding unit 7 has 64 first input ends 71 for receiving respectively first to 64^{th} reference voltages (V₁˜V₆₄), and a first output end 72, and is operable based on third to eighth bits B(7:2) of the digital input signal to output one of the first to 64^{th} reference voltages (V₁˜V₆₄) serving as a first decoding voltage (Vₒᵤₜ₁). The first decoding unit 7 includes 64 switch units 73_1˜73_64. Each of the switch units 73_1˜73_64 is connected electrically between a corresponding first input end 71 and the first output end 72, and includes six cascaded switches, each of which has a control end for receiving a corresponding one of the third to eighth bits B(7:2) of the digital input signal and is operable between an ON-state and an OFF-state in response to the corresponding one of the third to eighth bits B(7:2) of the digital input signal. In this case, a corresponding one of the switch units 73_1˜73_64 receiving said one of the first to 64^{th} reference voltages (V₁˜V₆₄) conducts, and the other ones of the switch units 73_1˜73_64 do not conduct. More specifically, all the switches of the corresponding one of the switch units 73_1˜73_64 are operated in the ON-state, and at least one switch in each of the other ones of the switch units 73_1˜73_64 is operated in the OFF-state.

The second decoding unit 8 has the same configuration as that of the first decoding unit 7. Similarly, the first decoding unit 8 has 64 second input ends 81 for receiving respectively second to 65^{th} reference voltages (V₂˜V₆₅), and a second output end 82, and is operable based on the third to eighth bits B(7:2) of the digital input signal to output one of the second to 65^{th} reference voltages (V₂˜V₆₅) serving as a second decoding voltage (Vₒᵤₜ₂). The second decoding unit 8 includes 64 switch units 83_1˜83_64. Each of the switch units 83_1˜83_64 is connected electrically between a corresponding second input end 81 and the second output end 82, and includes six cascaded switches, each of which has a control end for receiving a corresponding one of the third to eighth bits B(7:2) of the digital input signal and is operable between an ON-state and an OFF-state in response to the corresponding one of the third to eighth bits B(7:2) of the digital input signal. In this case, a corresponding one of the switch units 73_1˜73_64 receiving said one of the first to 64^{th} reference voltages (V₁˜V₆₄) conducts, and the other ones of the switch units 73_1˜73_64 do not conduct. More specifically, all the switches of the corresponding one of the switch units 73_1˜73_64 are operated in the ON-state, and at least one switch in each of the other ones of the switch units 73_1˜73_64 is operated in the OFF-state.

The output unit 9 includes a routing circuit 91 and an interpolating buffer 92 as disclosed in U.S. Pat. No. 6,326,913. The routing circuit 91 is connected electrically to the first and second output ends 72, 82 of the first and second decoding units 7, 8 for receiving the first and second decoding voltages (Vₒᵤₜ₁, Vₒᵤₜ₂), and receives a first and second bits B(1:0) of the digital input signal. The routing circuit 91 is configured to generate first, second, third and fourth voltages (V₁′, V₂′, V₃′, V₄′) based on the first and second decoding voltages (Vₒᵤₜ₁, Vₒᵤₜ₂) and the first and second bits B(1:0) of the digital input signal. The interpolating buffer 92 is connected electrically to the routing circuit 91 for receiving the first, second, third and fourth voltages (V₁′, V₂′, V₃′, V₄′) generated thereby, and is configured to generate the analog signal (V_{analog}) based on the first, second, third and fourth voltages (V₁′, V₂′, V₃′, V₄′). Accordingly, the output unit 9 is operable to generate the analog signal (V_{analog}) in accordance with the following Table 1.

TABLE 1

| B (1) | B (0) | V₄′ | V₃′ | V₂′ | V₁′ | V_{analog} |
|---|---|---|---|---|---|---|
| 0 | 0 | Vₒᵤₜ₁ | Vₒᵤₜ₁ | Vₒᵤₜ₁ | Vₒᵤₜ₁ | Vₒᵤₜ₁ |
| 0 | 1 | Vₒᵤₜ₂ | Vₒᵤₜ₁ | Vₒᵤₜ₁ | Vₒᵤₜ₁ | Vₒᵤₜ₁ + 0.25 × (Vₒᵤₜ₂ − Vₒᵤₜ₁) |
| 1 | 0 | Vₒᵤₜ₂ | Vₒᵤₜ₂ | Vₒᵤₜ₁ | Vₒᵤₜ₁ | Vₒᵤₜ₁ + 0.5 × (Vₒᵤₜ₂ − Vₒᵤₜ₁) |
| 1 | 1 | Vₒᵤₜ₂ | Vₒᵤₜ₂ | Vₒᵤₜ₂ | Vₒᵤₜ₁ | Vₒᵤₜ₁ + 0.75 × (Vₒᵤₜ₂ − Vₒᵤₜ₁) |

For example, when B(7:2) is “000000”, the switch unit 73_1 of the first decoding unit 7 and the switch unit 83_1 of the second decoding unit 8 conduct while the switch units 73_2˜73_64 of the first decoding unit 7 and the switch units 83_2˜83_64 do not conduct. As such, the reference voltage (V₁), i.e., 1V, is transmitted to the first output end 72 through the switch unit 73_1 and serves as the first decoding voltage (Vₒᵤₜ₁). At the same time, the reference voltage (V₂), i.e., 5V, is transmitted to the second output end 82 through the switch unit 83_1, and serves as the second decoding voltage (Vₒᵤₜ₂). In this case, when B(1:0) is “00”, “01”, “10” or “11”, the analog voltage (V_{analog}) is equal to 1V, 2(=1+0.25×(5−1))V, 3(=1+0.5×(5×1))V or 4(=1+0.75×(5−1))V. In the same way, when B(7:2) is “000001”, the switch unit 73_2 of the first decoding unit 7 and the switch unit 83_2 of the second decoding unit 8 conduct while the switch units 73_1, 73_3˜73_64 of the first decoding unit 7 and the switch units 83_1, 83_3˜83_64 do not conduct. As such, the reference voltage (V₂), i.e., 5V, is transmitted to the first output end 72 through the switch unit 73_2 and serves as the first decoding voltage (Vₒᵤₜ₁). At the same time, the reference voltage (V₃), i.e., 9V, is transmitted to the second output end 82 through the switch unit 83_2, and serves as the second decoding voltage (Vₒᵤₜ₂). In this case, when B(1:0) is “00”, “01”, “10” or “11”, the analog voltage (V_{analog}) is equal to 5V, 6(=5+0.25×(9−5))V, 7(=5+0.5×(9−5))V or 8(=5+0.75×(9−5))V. Similarly, when when B(7:2) is “111111”, the first and second decoding voltages (Vₒᵤₜ₁, Vₒᵤₜ₂) are respectively the reference voltages (V₆₄, V₆₅), i.e., 253V and 257V. In this case, when B(1:0) is “00”, “01”, “10” or “11”, the analog voltage (V_{analog}) is equal to 253V, 254(=253+0.25×(257−253))V, 255(=253+0.5×(257−253))V or 256(=253+0.75×(257×253))V. As a result, for any 8-bit digital input signal having one of 256(=2⁸) bit combinations, the conventional digital-to-analog converting device can generate a specific analog signal.

However, in such a configuration, there are at least 768(=128×6) switches used in the conventional 8-bit digital-to-analog converting device 900, thereby resulting in a relatively high cost. Therefore, improvements may be made to the above techniques.

### SUMMARY OF THE INVENTION

Therefore, an object of the present invention is to provide a digital-to-analog converting device that can overcome the aforesaid drawbacks of the prior art.

According to the present invention, there is provided a digital-to-analog converting device for converting an N-bit digital input signal into an analog signal using a number (M) of reference voltages forming an arithmetic progression, where N>3 and M=2^{(N-2)}+1. The digital-to-analog converting device comprises:

a decoding unit adapted to receive the reference voltages and third to N^{th}bits of the digital input signal, the decoding unit being operable based on the third to N^{th} bits of the digital input signal and the reference voltages to output a first decoding voltage and a second decoding voltage, the decoding unit including

a number (K) of first selectors each having first and second input ends, and an output end, where K=2^{(N-3)}+1, the first and second input ends of an i^{th} one of the first selectors being adapted to receive an i^{th} and (K+i−1)^{th} ones of the reference voltages, respectively, such that the i^{th} one of the first selectors is operable based on the N^{th} bit of the digital input signal to output, at the output end, one of the i^{th} and (K+i−1)^{th} ones of the reference voltages serving as an output voltage, where i=1, 2, . . . , K, and

a second selector connected electrically to the output ends of the first selectors for receiving the output voltages therefrom, and adapted to receive the third to (N−1)^{th} bits of the digital input signal, the second selector being operable based on the third to (N−1)^{th} bits of the digital input signal to output two of the output voltages that serve respectively as the first and second decoding voltages; and

an output unit connected electrically to the second selector for receiving the first and second decoding voltages therefrom, and adapted to receives a first and second bits of the digital input signal, the output unit being operable based on the first and second decoding voltages and the first and second bits of the digital input signal to generate the analog signal.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic electrical circuit block diagram illustrating a conventional digital-to-analog converting device for converting an 8-bit digital input signal into an analog signal;

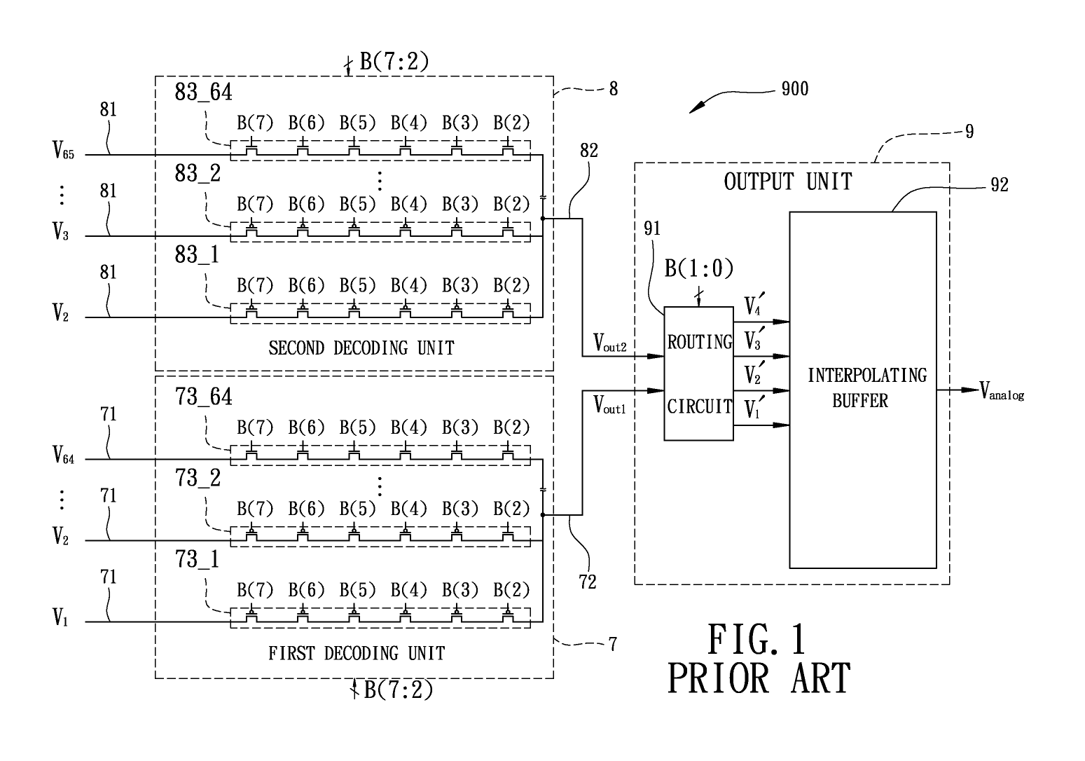

FIG. 2 is a schematic electrical circuit block diagram illustrating the preferred embodiment of a digital-to-analog converting device according to the present invention; and

FIG. 3 is a schematic electrical circuit block diagram illustrating an example of the preferred embodiment for converting an 8-bit digital input signal into an analog signal.

### DETAILED DESCRIPTION OF THE PREFERRED EMBODIMENT

Before the present invention is described in greater detail, it should be noted that like elements are denoted by the same reference numerals throughout the disclosure.

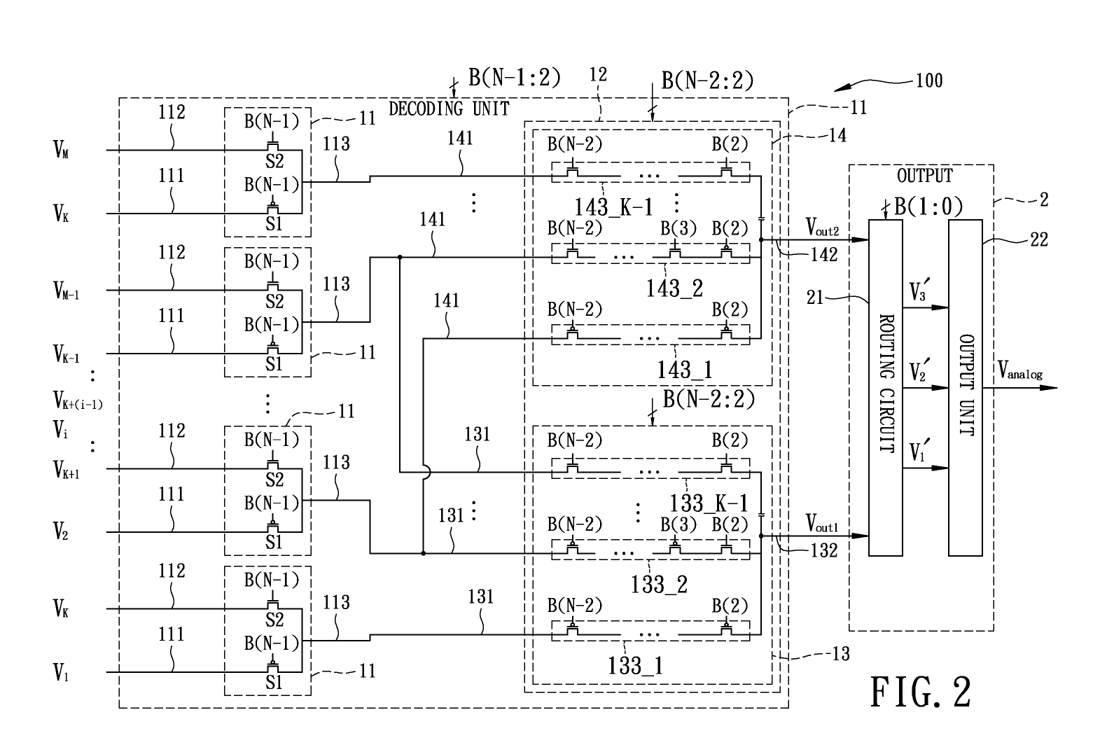

Referring to FIG. 2, the preferred embodiment of a digital-to-analog converting device 100 according to the present invention is shown to be adapted for converting an N-bit digital input signal into an analog signal using a number (M) of reference voltages (V₁˜V_{M}) forming an arithmetic progression, where N>3 and M=2^{(N-2)}+1. The digital input signal has N bits indicated by B(N−1:0). The digital-to-analog converting device 100 includes a decoding unit 1, and an output unit 2.

The decoding unit 1 is adapted to receive the reference voltages (V₁˜V_{M}) and third to N^{th} bits B(N−1:2) of the digital input signal, and is operable based on the third to N^{th} bits B(N−1:2) of the digital input signal and the reference voltages (V₁˜V_{M}) to output a first decoding voltage (Vₒᵤₜ₁) and a second decoding voltage (Vₒᵤₜ₂) wherein the first decoding voltage (Vₒᵤₜ₁) is less than the second decoding voltage (Vₒᵤₜ₂). The decoding unit 1 includes a number (K) of first selectors 11, and a second selector 12, where K=2^{(N-3)+}1.

Each first selector 11 has first and second input ends 111, 112, and an output end 113. The first and second ends 111, 112 of an i^{th} one of the first selectors 11 are adapted to receive an i^{th} and (K+i−1)^{th} reference voltages (Vᵢ, V_{K+i-1}), respectively, such that the i^{th} one of the first selectors 11 is operable based on the N^{th} bit B(N−1) of the digital input signal to output, at the output end 113, one of the i^{th} and (K+i−1)^{th} reference voltages (Vᵢ, V_{K+i-1}) serving as an output voltage, where i=1, 2, . . . , K. In this embodiment, each first selector 11 includes a first switch (S1), and a second switch (S2). For each first selector 11, the first switch (S1) has a first end serving as the first input end 111, a second end coupled to the output end 113, and a control end adapted for receiving the N^{th} bit B(N−1) of the digital input signal such that the first switch (S1) is operable between an ON-state and an OFF-state in response to the N^{th} bit B(N−1) of the digital input signal. The second switch (S2) has a first end serving as the second input end 112, a second end coupled to the output end 113, and a control end adapted for receiving the N^{th} bit B(N−1) of the digital input signal such that the second switch (S2) is operable between an ON-state and an OFF-state in response to the N^{th} bit B(N−1) of the digital input signal. It is noted that, for each first selector 11, one of the first and second switches (S1, S2) is operated in the ON-state, and the other one of the first and second switches (S1, S2). In this embodiment, for each first selector 11, the first switch (S1) is a P-type MOS field effect transistor, and the second switch (S2) is an N-type MOS field effect transistor. For example, if B(N−1) is “0”, the first switches (S1) are in the ON-state and the second switches (S2) are in the OFF-state such that the first selectors 11 output respectively the reference voltages (V₁˜V_{K}). If B(N−1) is “1”, the first switches (S1) are in the OFF-state and the second switches (S2) are in the ON-state such that the first selectors 11 output respectively the reference voltages (V_{K}˜V_{M}).

The second selector 12 is connected electrically to the output ends 113 of the first selectors 11 for receiving the output voltages therefrom, and is adapted to receive the third to (N−1)^{th} bits B(N−2:2) of the digital input signal. The second selector 12 is operable based on the third to (N−1)^{th} bits B(N−2:2) of the digital input signal to output two of the output voltages that serve respectively as the first and second decoding voltages (Vₒᵤₜ₁, Vₒᵤₜ₂). The second selector 12 includes a first decoding circuit 13, and a second decoding circuit 14.

The first decoding circuit 13 has a number (K−1) of first end input ends 131 coupled respectively to the output ends 113 of first to (K−1)^{th} ones of the first selectors 11 for receiving the output voltages therefrom, and a first output end 132 for outputting the first decoding voltage (Vₒᵤₜ₁). In this embodiment, the first decoding circuit 13 including a number (K−1) of switch units 133_1˜1_33 K−1 each connected electrically between a corresponding one of the number (K−1) of the first input ends 131 and the first output end 132 of the first decoding circuit 13. Each of the switch units 133_1˜133_K−1 includes a number (N−3) of cascaded switches, each of which has a control end adapted for receiving a corresponding one of the third to (N−1)^{th} bits B(N−2:2) of the digital input signal such that each of the switches is operable between an ON-state and an OFF-state in response to the corresponding one of the third to (N−1)^{th} bits B(N−2:2) of the digital input signal. It is noted that all the switches of one of the switch units 133_1˜133_K−1 are operated in the ON-state, and at least one of the switches of each of the other ones of the switch units 133_1˜133_K−1 is operated in the OFF-state such that the output voltage received by said one of the switch units 133_1˜133_K−1 is transmitted to the first output end 132 through said one of the switch units 133_1˜133_K−1, and serves as the first decoding voltage (Vₒᵤₜ₁).

Similar to the first decoding circuit 13, the second decoding circuit 14 has a number (K−1) of second input ends 141 coupled respectively to the output ends 113 of the second to K^{th} ones of the first selectors 11 for receiving the output voltages therefrom, and a second output end 142 for outputting the second decoding voltage (Vₒᵤₜ₂). The second decoding circuit 14 includes a number (K−1) of switch units 143_1˜143_K−1 each connected electrically between a corresponding one of the number (K−1) of the second input ends 141 and the second output end 142. Each of the switch units 143_1˜143_K−1 includes a number (N−3) of cascaded switches, each of which has a control end adapted for receiving a corresponding one of the third to (N−1)^{th} bits B(N−2:2) of the digital input signal such that each of the switches is operable between an ON-state and an OFF-state in response to the corresponding one of the third to (N−1)^{th} bits B(N−2:2) of the digital input signal. It is noted that all the switches of one of said switch units 143_1˜143_K−1 are operated in the ON-state, and at least one of the switches of each of the other ones of the switch units 143_1˜143_K−1 is operated in the OFF-state such that the output voltage received by said one of said switch units 143_1˜143_K−1 is transmitted to the second output end 142 through said one of said switch units 143_1˜143_K−1, and serves as the second decoding voltage (Vₒᵤₜ₁).

In this embodiment, a j^{th} one of the switch units 133_1˜133_K−1 of the first decoding circuit 13 is identical to a j^{th} one of the switch units 143_1˜143_K−1 of the second decoding circuits, where j=1, 2, . . . , K−1. In addition, for each of the first and second decoding circuits 13,14 of the second selector 12, each switch of the first switch unit 133_1/143_1 is a P-type MOS field effect transistor, each switch of the (K−1)^{th} switch unit 133_K−1/143_K−1 is an N-type MOS field effect transistor, and each switch of each of the second to (K-2)^{th} switch units 133_2˜133_K−2/143_2˜143_K−2 is one of a P-type MOS field effect transistor and an N-type MOS field effect transistor, as shown in FIG. 2.

The output unit 2 is connected electrically to the first output end 132 of the first decoding circuit 13 and the second output end 142 of the second decoding circuit 14 for receiving the first and second decoding voltages (Vₒᵤₜ₁, Vₒᵤₜ₂) therefrom, and is adapted to receive a first and second bits B(1:0) of the digital input signal. The output unit 2 is operable based on the first and second decoding voltages (Vₒᵤₜ₁, Vₒᵤₜ₂) and the first and second bits B(1:0) of the digital input signal to generate the analog signal (V_{analog}). In this embodiment, the output unit 2 includes a routing circuit 21, and an interpolating buffer 22.

The routing circuit 21 is connected electrically to the first and output ends 132, 142 of the first and second decoding circuits 13, 14 of the second selector 12 for receiving the first and second decoding voltages (Vₒᵤₜ₁, Vₒᵤₜ₂) therefrom, and is adapted to receive the first and second bits B(1:0) of the digital input signal. The routing circuit 21 is configured to generate first, second and third output voltages (V₁′, V₂′, V₃′) based on the first and second decoding voltages (Vₒᵤₜ₁, Vₒᵤₜ₂) and the first and second bits B(1:0) of the digital input signal, wherein the first decoding voltage (Vₒᵤₜ₁) serves as the first output voltage (V₁′), each of the second and third output voltages (V₂′, V₃′) is one of the first and second decoding voltages (Vₒᵤₜ₁, Vₒᵤₜ₂). Since the feature of this invention does not reside in the configuration of the routing circuit 21, which is disclosed in U.S. Pat. No. 6,326,913, details of the same are omitted herein for the sake of brevity.

The interpolating buffer 22 is connected electrically the routing circuit 21 for receiving the first, second and third output voltages (V₁′, V₂′, V₃′) therefrom, and is configured to generate the analog signal based on the first, second and third output voltages (V₁′, V₂′, V₃′). Since the feature of this invention does not reside in the configuration of the the interpolating buffer, which are disclosed in U.S. Pat. No. 6,326,913, details of the same are omitted herein for the sake of brevity. In this embodiment, the analog signal (V_{analog}) generated by the interpolating buffer 22 is configured to be a voltage equal to a sum of the first output voltage (V₁′), one half of a difference between the second and first output voltages (V₂′, V₁′), and a quarter of a difference between the third and second output voltages (V₃′, V₁′). That is, V_{analog}=V₁′+0.5×(V₂′−V₁′)+0.25×(V₃′−V₁′).

As a result, the output unit 2 is operable to generate the analog signal (V_{analog}) in accordance with the following Table 2.

TABLE 2

| B (1) | B (0) | V₃′ | V₂′ | V₁′ | V_{analog} |
|---|---|---|---|---|---|
| 0 | 0 | Vₒᵤₜ₁ | Vₒᵤₜ₁ | Vₒᵤₜ₁ | Vₒᵤₜ₁ |
| 0 | 1 | Vₒᵤₜ₂ | Vₒᵤₜ₁ | Vₒᵤₜ₁ | Vₒᵤₜ₁ + 0.25 × (Vₒᵤₜ₂ − Vₒᵤₜ₁) |
| 1 | 0 | Vₒᵤₜ₁ | Vₒᵤₜ₂ | Vₒᵤₜ₁ | Vₒᵤₜ₁ + 0.5 × (Vₒᵤₜ₂ − Vₒᵤₜ₁) |
| 1 | 1 | Vₒᵤₜ₂ | Vₒᵤₜ₂ | Vₒᵤₜ₁ | Vₒᵤₜ₁ + 0.75 × (Vₒᵤₜ₂ − Vₒᵤₜ₁) |

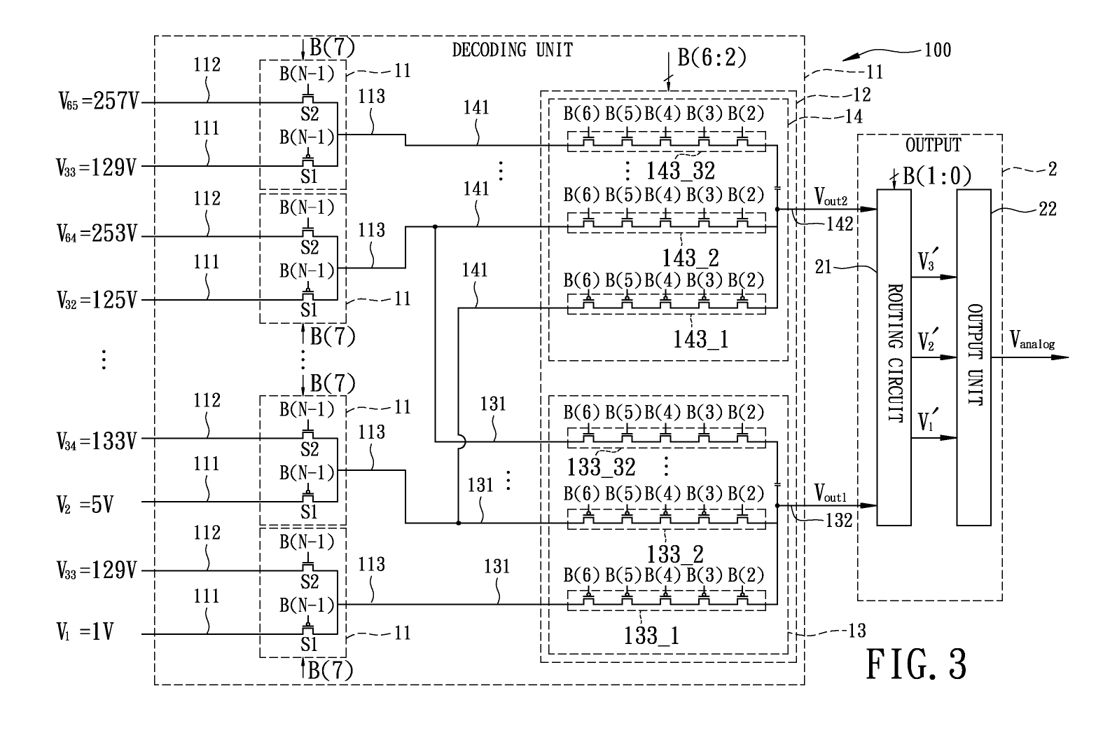

FIG. 3 illustrates an example of the digital-to-analog converting device 100 for converting a digital input signal with 8 bits indicated by B(7:0) into an analog signal (V_{analog}) using 65(=2⁽⁸⁻²⁾+1) reference voltages (V₁˜V₆₅) forming an arithmetic progression, wherein V₁=1V, V₂=5V, V₃=9V, V₄=13V, V₆₄=253V, and V₆₅=257V. In this example, N=8, M=2⁽⁸⁻²⁾+1=65, and K=2⁽⁸⁻³⁾+1=33. Thus, the decoding unit 1 includes 65 first selectors 11, each of which receives corresponding two of the reference voltages (V₁˜V₆₅) and the bit B(7) of the digital input signal. Each of the first and second decoding circuits 13, 14 of the second selector 12 includes 32 switch units 133_1˜133_32/143_1˜143_{≦}32, each of which receives the output voltage from a corresponding one of the first selectors 11, and the third to seventh bits B(6:2) of the digital input signal, and includes five switches. As a result, if B(7:0) is “0000000”, the first selectors 11 output respectively the reference voltages (V₁˜V₃₃) serving as the output voltages, the first switch unit 133_1/143_1 of each of the first and second decoding circuits 13, 24 conducts such that the reference voltages (V₁, V₂) are received by the first switch units 133_1, 143_1 and transmitted to the first and second output ends 132, 142 of the first and second decoding circuits 13, 14, respectively, and serve respectively as the first and second decoding voltages (Vₒᵤₜ₁, Vₒᵤₜ₂), i.e., Vₒᵤₜ₁=1V and Vₒᵤₜ₂=5V. Then, according to Table 2, the first, second and third output voltages (V₁′, V₂′, V₃′) are the first decoding voltage (Vₒᵤₜ₁), and the analog signal (V_{analog}) is the first decoding voltage (Vₒᵤₜ₁), i.e., V_{analog}=1V. If B(7:0) is “0000001”, V₁′=1V, V₂′=1V, V₃′=5V, and V_{analog}=1V+0.25×(5V−1V)=2V. Similarly, if B(7:0) is “1111111”, V₁′=253V, V₂′=257V, V₃′=257V, and V_{analog}=253V+0.75>(257V−253V)=256V. As a result, for any 8-bit digital input signal having one of 256(=2⁸) bit combinations, the digital-to-analog converting device of this invention can generate a specific analog signal (V_{analog}). It is noted that, in this case, there are totally 386(=33×2+5×(32+32)) switches in the decoding unit 1 that are greatly less than 768 switches required in the first and second decoding units 7, 8 of the aforesaid conventional 8-bit digital-to-analog converting device 900.

In sum, the digital-to-analog converting device of the present invention utilizes the reduced number of the switches compared to the prior art, thereby resulting in a relatively low cost.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A digital-to-analog converting device for converting an N-bit digital input signal into an analog signal using a number (M) of reference voltages forming an arithmetic progression, where N>3 and M=2^{(N-2)}+1, said digital-to-analog converting device comprising:
a decoding unit adapted to receive the reference voltages and third to N^{th}bits of the digital input signal, said decoding unit being operable based on the third to N^{th} bits of the digital input signal and the reference voltages to output a first decoding voltage and a second decoding voltage, said decoding unit including a number (K) of first selectors each having first and second input ends, and an output end, where K=2^{(N-3)}+1, said first and second input ends of an i^{th} one of said first selectors being adapted to receive an i^{th} and (K+i−1)^{th} ones of the reference voltages, respectively, such that the i^{th} one of said first selectors is operable based on the N^{th} bit of the digital input signal to output, at said output end, one of the i^{th} and (K+i−1)^{th} ones of the reference voltages serving as an output voltage, where i=1, 2, . . . , K, and
a second selector connected electrically to said output ends of said first selectors for receiving the output voltages therefrom, and adapted to receive the third to (N−1)^{th} bits of the digital input signal, said second selector being operable based on the third to (N−1)^{th} bits of the digital input signal to output two of the output voltages that serve respectively as the first and second decoding voltages; and
an output unit connected electrically to said second selector for receiving the first and second decoding voltages therefrom, and adapted to receives a first and second bits of the digital input signal, said output unit being operable based on the first and second decoding voltages and the first and second bits of the digital input signal to generate the analog signal.

2. The digital-to-analog converting device as claimed in claim 1, wherein each of said first selectors includes
a first switch having a first end serving as said first input end, a second end coupled to said output end, and a control end adapted for receiving the N^{th} bit of the digital input signal such that said first switch is operable between an ON-state and an OFF-state in response to the N^{th} bit of the digital input signal, and
a second switch having a first end serving as said second input end, a second end coupled to said output end, and a control end adapted for receiving the N^{th} bit of the digital input signal such that said second switch is operable between an ON-state and an OFF-state in response to the N^{th} bit of the digital input signal; and
wherein, for each of said first selectors, one of said first and second switches is operated in the ON-state, and the other one of said first and second switches is operated in the OFF-state.

3. The digital-to-analog converting device as claimed in claim 2, wherein, for each of said first selectors, said first switch is a P-type MOS field effect transistor, and said second switch is an N-type MOS field effect transistor.

4. The digital-to-analog converting device as claimed in claim 2, wherein said second selector includes a first decoding circuit having a number (K−1) of first input ends coupled respectively to said output ends of first to (K−1)^{th} ones of said first selectors for receiving the output voltages therefrom, and a first output end connected electrically to said output unit for outputting the first decoding voltage, said first decoding circuit including a number (K−1) of switch units each connected electrical ly between a corresponding one of the number (K−1) of said first input ends and said first output end of said first decoding circuit, each of said switch units of said first decoding circuit including a number (N−3) of cascaded switches, each of which has a control end adapted for receiving a corresponding one of the third to (N−1)^{th} bits of the digital input signal such that each of said switches is operable between an ON-state and an OFF-state in response to the corresponding one of the third to (N−1) th bits of the digital input signal, and
a second decoding circuit having a number (K−1) of second input ends coupled respectively to said output ends of the second to K^{th} ones of said first selectors for receiving the output voltages therefrom, and a second output end connected electrically to said output unit for outputting the second decoding voltage, said second decoding circuit including a number (K−1) of switch units each connected electrically between a corresponding one of the number (K−1) of said second input ends and said second output end of said second decoding circuit, each of said switch units of said second decoding circuit including a number (N−3) of cascaded switches, each of which has a control end adapted for receiving a corresponding one of the third to (N−1)^{th} bits of the digital input signal such that each of said switches is operable between an ON-state and an OFF-state in response to the corresponding one of the third to (N−1) th bits of the digital input signal;
wherein, for said first decoding circuit, all said switches of one of said switch units are operated in the ON-state, and at least one of said switches of each of the other ones of said switch units is operated in the OFF-state such that the output voltage received by said one of said switch units is transmitted to said first output end through said one of said switch units, and serves as the first decoding voltage; and
wherein, for said second decoding circuit, all said switches of one of said switch units are operated in the ON-state, and at least one of said switches of each of the other ones of said switch units is operated in the OFF-state such that the output voltage received by said one of said switch units is transmitted to said second output end through said one of said switch units, and serves as the second decoding voltage.

5. The digital-to-analog converting device as claimed in claim 4, wherein:
a j^{th} one of said switch units of said first decoding circuit is identical to a j^{th} one of said switch units of said second decoding circuits, where j=1, 2, . . . , K−1; and
for each of said first and second decoding circuits of said second selector,
each of said switches of the first one of said switch units is a P-type MOS field effect transistor;
each of said switches of the (K−1)^{th} one of said switch units is an N-type MOS field effect transistor;
each of said switches of each of the second to (K−2)^{th} ones of said switch units is one of a P-type MOS field effect transistor and an N-type MOS field effect transistor.

6. The digital-to-analog converting device as claimed in claim 4, wherein:
the first decoding voltage is less than the second decoding voltage; and
said output unit includes
a routing circuit connected electrically to said first and second output ends of said first and second decoding circuits of said second selector for receiving the first and second decoding voltages, and adapted to receive the first and second bits of the digital input signal, said routing circuit being configured to generate first, second and third output voltages based on the first and second decoding voltages and the first and second bits of the digital input signal, the first decoding voltage serving as the first output voltage, each of the second and third output voltages being one of the first and second decoding voltages, and
an interpolating buffer connected electrically to said routing circuit for receiving the first, second and third output voltages therefrom, and configured to generate the analog signal based on the first, second and third output voltages.

7. The digital-to-analog converting device as claimed in claim 6, wherein the analog signal generated by said output unit is a voltage equal to a sum of the first output voltage, one half of a difference between the second and first output voltages, and a quarter of a difference between the third and first output voltages.
